(19) United States
(12) Patent Application Publication
(10) Pub. No.: US 2005/0012026 A1
(43) Pub. Date: Jan. 20, 2005

(54) Image sensor and method for packaging the same

(76) Inventors: Jackson Hsieh, Hsinchu Hsien (TW); Jichen Wu, Hsinchu Hsien (TW); Shuen Yang JR., Hsinchu Hsien (TW); Worrell Tsai, Hsinchu Hsien (TW)

Correspondence Address: PRO-TECHTOR INTERNATIONAL SERVICES, 20775 Norada Court, Saratoga, CA, 95070-3018, US

(21) Appl. No.: 10/621,990

(22) Filed: Jul. 16, 2003

(51) Int. Cl. H01L 27/00; H01L 31/00

(52) U.S. Cl. 250/208.1; 250/214.1

(57) ABSTRACT

An image sensor includes a lower metal sheet set, an upper metal sheet set, an encapsulant, a photosensitive chip, plural wires, and a transparent layer. The lower metal sheet set includes plural lower metal sheets and a lower middle board arranged among and flush with the lower metal sheets. The upper metal sheet set includes plural upper metal sheets and an upper middle board arranged among and flush with the upper metal sheets. The encapsulant encapsulates the lower metal sheets, lower middle board, upper metal sheets and upper middle board with the upper metal sheets, lower metal sheets, lower middle board, and upper middle board exposed from the encapsulant, and with a frame layer formed around the upper metal sheets to define a chamber. The photosensitive chip is arranged on the upper surface of the upper middle board and located within the chamber.

### BACKGROUND OF THE INVENTION

1. Field of the Invention

The invention relates to an image sensor and a method for packaging the same, and more particularly to an image sensor and a method for packaging the same with increased product reliability, improved radiation effects, and facilitated packaging processes.

2. Description of the Related Art

Referring to FIG. 1, which is a cross-sectional view showing an image sensor disclosed in a commonly-assigned, copending U.S. patent application Ser. No. 10/146,997, filed on May 15, 2002. The image sensor 1 includes a substrate 10, a frame layer 18, a photosensitive chip 22, a plurality of wires 24, and a transparent layer 27. The substrate 10 is composed of a plurality of metal sheets 12 arranged in an array. Each of the metal sheets 12 has a first board 14 and a second board 16 at different levels. The frame layer 18 is formed at a periphery and a bottom surface of the substrate 10 to form a chamber 20 together with the substrate 10. Top surfaces of the first boards 14 and bottom surfaces of the second boards 16 are exposed from the frame layer 18. The photosensitive chip 22 is arranged within the chamber 20 defined by the frame layer 18 and the substrate 10. The wires 24 electrically connect the top surfaces of the first boards 14 of the metal sheets 12 to the photosensitive chip 22. The transparent layer 26 is arranged on the frame layer 18 to cover the photosensitive chip 22.

However, the above-mentioned structure has the following drawbacks.

1. Since the metal sheets 12 are bent to form the first boards 14 and second boards 16 at different levels, the formed first boards 14 may be uneven. Therefore, the wires 24 cannot be conveniently bonded to the metal sheets 12, and the yield may be influenced.

2. Since the thickness of each of the second boards 16 of the metal sheets 12 is thinner (because each metal sheet 12 with greater thickness cannot be pressed during the manufacturing processes), the solder tin cannot climb to the lateral side of each metal sheet 12 during the SMT process. Therefore, the package body cannot be mounted to the printed circuit board with great stability.

3. Since the bottom surface of the photosensitive chip 22 is enclosed by the frame layer 18, better radiation effects cannot be obtained.

### SUMMARY OF THE INVENTION

An object of the invention is to provide an image sensor with increased thickness of the combined metal sheets and better radiation effects, and a method for packaging the same with improved package reliability.

Another object of the invention is to provide an image sensor and a method for packaging the same, wherein the solder tin may climb higher during the SMT process and the image sensor may be mounted to the printed circuit board with great stability.

Still another object of the invention is to provide an image sensor and a method for packaging the same, wherein the wire bonding process may be easily performed and the product yield may be increased.

To achieve the above-mentioned objects, the invention provides an image sensor to be electrically connected to a printed circuit board. The image sensor includes a lower metal sheet set, an upper metal sheet set, an encapsulant, a photosensitive chip, a plurality of wires, and a transparent layer.

The lower metal sheet set includes a plurality of lower metal sheets arranged in an array and a lower middle board arranged among and flush with the lower metal sheets. Each of the lower metal sheets has an upper surface and a lower surface, and the lower middle board has an upper surface and a lower surface.

The upper metal sheet set includes a plurality of upper metal sheets arranged in an array and an upper middle board arranged among and flush with the upper metal sheets. Each of the upper metal sheets has an upper surface and a lower surface, the lower surfaces of the upper metal sheets are stacked on the upper surfaces of the lower metal sheets, respectively, the upper middle board has an upper surface and a lower surface, and the lower surface of the upper middle board is correspondingly stacked on the upper surface of the lower middle board.

The encapsulant encapsulates the lower metal sheets, the lower middle board, the upper metal sheets and the upper middle board with the upper surfaces of the upper metal sheets, the lower surfaces of the lower metal sheets, the lower surface of the lower middle board, and the upper surface of the upper middle board exposed from the encapsulant, and with a frame layer formed around the upper surfaces of the upper metal sheets to define a chamber together with the upper metal sheets. The exposed lower surfaces of the lower metal sheets are electrically connected to the printed circuit board;

The photosensitive chip is arranged on the upper surface of the upper middle board and located within the chamber. The wires electrically connect the photosensitive chip to the upper surfaces of the upper metal sheets. The transparent layer is arranged on the frame layer of the encapsulant to cover the photosensitive chip.

### BRIEF DESCRIPTION OF THE DRAWINGS

FIG. 1 is a cross-sectional view showing an image sensor disclosed in a commonly-assigned, copending U.S. patent application Ser. No. 10/146,997, filed on May 15, 2002.

FIG. 2 is a cross-sectional view showing an image sensor of the invention.

FIG. 3 is a first schematic illustration showing a method for packaging the image sensor of the invention.

FIG. 4 is a second schematic illustration showing the method for packaging the image sensor of the invention.

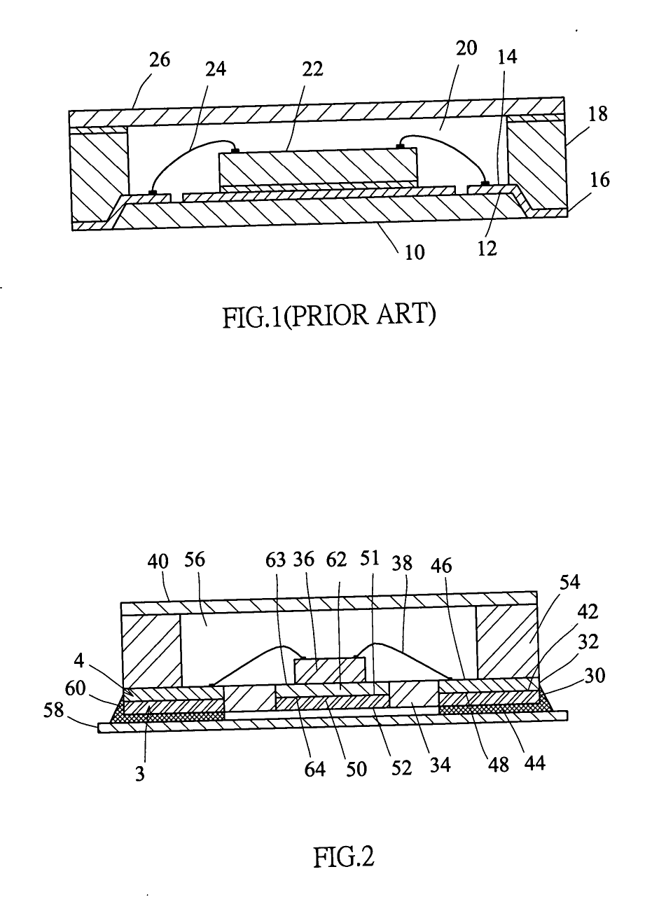

### DETAILED DESCRIPTION OF THE INVENTION

Referring to FIG. 2, an image sensor of the invention includes a lower metal sheet set 3, an upper metal sheet set 4, an encapsulant 34, a photosensitive chip 36, a plurality of wires 38, and a transparent layer 40.

The lower metal sheet set 3 includes a plurality of lower metal sheets 30 arranged in an array and a lower middle board 50 arranged among and flush with the lower metal sheets 30. Each lower metal sheet 30 has an upper surface 42 and a lower surface 44 mounted to a printed circuit board 58 via solder tin 60 in the SMT process. The middle board 50 has an upper surface 51 and a lower surface 52.

The upper metal sheet set 4 includes a plurality of upper metal sheets 32 arranged in an array and an upper middle board 62 arranged among and flush with the upper metal sheets 32. Each upper metal sheet 32 has an upper surface 46 and a lower surface 48 correspondingly stacked on the upper surface 42 of the lower metal sheet 30. The upper middle board 62 has an upper surface 63 and a lower surface 64. The lower surface 64 of the upper middle board 62 is correspondingly stacked on the upper surface 51 of the lower middle board 50.

The encapsulant 34 encapsulates the plurality of lower metal sheets 30, a lower middle board 50, the plurality of upper metal sheets 32 and the upper middle board 62 with the upper surfaces 46 of the upper metal sheets 32, the lower surfaces 44 of the lower metal sheets 30, the lower surface 52 of the lower middle board 50 and the upper surface 63 of the upper middle board 62 exposed from the encapsulant 34. Simultaneously, a frame layer 54 is formed around the upper surfaces 46 of the upper metal sheets 32 to define a chamber 56 together with the upper metal sheets 32. The exposed lower surfaces 44 of the lower metal sheets 30 are to be electrically connected to the printed circuit board 58.

The photosensitive chip 36 is arranged on the upper surface 63 of the upper middle board 62 and located within the chamber 56.

The plurality of wires 38 electrically connect the photosensitive chip 36 to the upper surfaces 46 of the upper metal sheets 32 so as to transfer signals from the photosensitive chip 36 to the upper metal sheets 32.

The transparent layer 40 is a piece of transparent glass arranged on the frame layer 54 of the encapsulant 34 to cover the photosensitive chip 36. Thus, the photosensitive chip 36 may receive optical signals passing through the transparent layer 40.

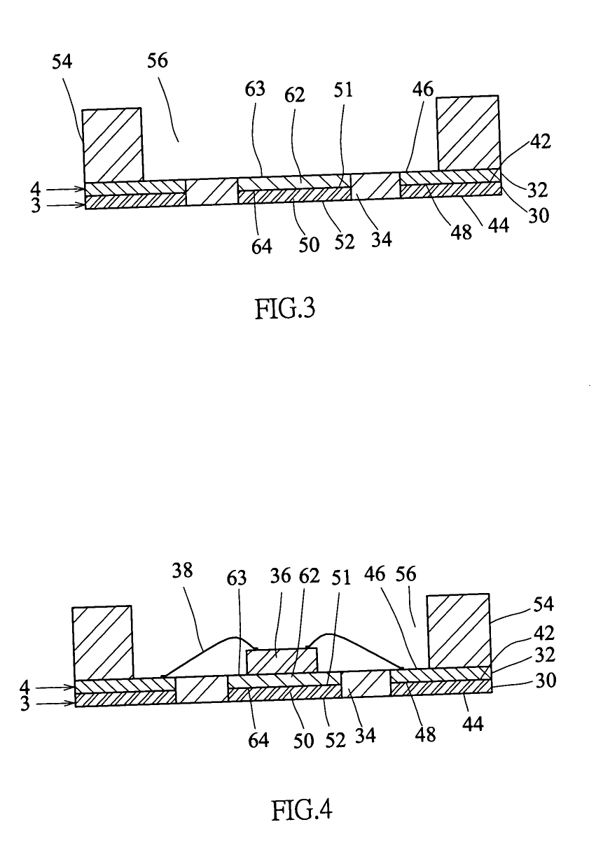

Referring to FIG. 3, a method for packaging an image sensor of the invention includes the steps of:
providing a lower metal sheet set 3, which includes a plurality of lower metal sheets 30 arranged in an array and an upper middle board 50 arranged among and flush with the lower metal sheets 30, each lower metal sheet 30 having an upper surface 42 and a lower surface 44, and the middle board 50 having an upper surface 51 and a lower surface 52;
providing an upper metal sheet set 4 including a plurality of upper metal sheets 32 arranged in an array and an upper middle board 62 arranged among and flush with the upper metal sheets 32, each upper metal sheet 32 having an upper surface 46 and a lower surface 48 correspondingly stacked on the upper surface 42 of the lower metal sheet 30, the upper middle board 62 having an upper surface 63 and a lower surface 64, and the lower surface 64 of the upper middle board 62 being correspondingly stacked on the upper surface 51 of the lower middle board 50; and
providing an encapsulant 34, which is made of industrial plastic material and formed by way of injection molding, to encapsulate the lower metal sheets 30, the lower middle board 50, the upper metal sheets 32 and the upper middle board 62 with the upper surfaces 46 of the upper metal sheets 32, the lower surfaces 44 of the lower metal sheets 30, the lower surface 52 of the lower middle board 50 and the upper surface 63 of the upper middle board 62 exposed from the encapsulant 34, wherein a frame layer 54 is simultaneously formed around the upper surfaces 46 of the upper metal sheets 32 to define a chamber 56 together with the upper metal sheets 32.

Referring also to FIG. 4, the method of the invention further includes the steps of:
arranging a photosensitive chip 36 on the upper surface 63 of the upper middle board 62 and within the chamber 56;
providing a plurality of wires 38 to electrically connect the photosensitive chip 36 to the upper surfaces 46 of the upper metal sheets 32 so as to transfer signals from the photosensitive chip 36 to the upper metal sheets 32; and
arranging a transparent layer 40, which is a piece of transparent glass, on the frame layer 54 of the encapsulant 34 to cover the photosensitive chip 36 so that the photosensitive chip 36 may receive optical signals passing through the transparent layer 40.

The invention has the following advantages.

1. Since the upper and lower metal sheets 32 and 30 are formed from two flat boards, better smoothness may be obtained. Consequently, the wire bonding process may be easily performed, and the package yield of the product may be improved.

2. Since the combination of the upper and lower metal sheets 32 and 30 is thicker, the solder tin 60 may climb to the upper metal sheets 32 from the lower metal sheets 30 during the SMT process for mounting the image sensor to the printed circuit board 58. Therefore, the package body can be mounted to the printed circuit board 58 with great stability.

3. Since the photosensitive chip 36 is arranged on the upper surface 63 of the upper middle board 62, the lower surface 64 of the upper middle board 62 is stacked above the upper surface 51 of the lower middle board 50, and the lower surface 52 of the lower middle board 50 is exposed from the encapsulant 34, the heat generated from the photosensitive chip 36 may be well dissipated via the lower surface 52 of the lower middle board 50.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. An image sensor to be electrically connected to a printed circuit board, the image sensor comprising:
a lower metal sheet set including a plurality of lower metal sheets arranged in an array and a lower middle board arranged among and flush with the lower metal sheets, each of the lower metal sheets having an upper surface and a lower surface, and the lower middle board having an upper surface and a lower surface;
an upper metal sheet set including a plurality of upper metal sheets arranged in an array and an upper middle board arranged among and flush with the upper metal sheets, each of the upper metal sheets having an upper surface and a lower surface, the lower surfaces of the upper metal sheets being stacked on the upper surfaces of the lower metal sheets, respectively, the upper middle board having an upper surface and a lower surface, and the lower surface of the upper middle board being correspondingly stacked on the upper surface of the lower middle board;
an encapsulant for encapsulating the lower metal sheets, the lower middle board, the upper metal sheets and the upper middle board with the upper surfaces of the upper metal sheets, the lower surfaces of the lower metal sheets, the lower surface of the lower middle board, and the upper surface of the upper middle board exposed from the encapsulant, and with a frame layer formed around the upper surfaces of the upper metal sheets to define a chamber together with the upper metal sheets, the exposed lower surfaces of the lower metal sheets being electrically connected to the printed circuit board;
a photosensitive chip arranged on the upper surface of the upper middle board and located within the chamber;
a plurality of wires for electrically connecting the photosensitive chip to the upper surfaces of the upper metal sheets; and
a transparent layer arranged on the frame layer of the encapsulant to cover the photosensitive chip.

2. The image sensor according to claim 1, wherein the encapsulant is made of industrial plastic material, and the encapsulant and the frame layer are integrally formed.

3. The image sensor according to claim 1, wherein the transparent layer is a piece of transparent glass.

4. A method for packaging an image sensor, comprising the steps of:
providing a lower metal sheet set including a plurality of lower metal sheets arranged in an array and a lower middle board arranged among and flush with the lower metal sheets, each of the lower metal sheets having an upper surface and a lower surface, and the lower middle board having an upper surface and a lower surface;
providing an upper metal sheet set including a plurality of upper metal sheets arranged in an array and an upper middle board arranged among and flush with the upper metal sheets, each of the upper metal sheets having an upper surface and a lower surface, the lower surfaces of the upper metal sheets being stacked on the upper surfaces of the lower metal sheets, respectively, the upper middle board having an upper surface and a lower surface, and the lower surface of the upper middle board being correspondingly stacked on the upper surface of the lower middle board;
providing an encapsulant for encapsulating the lower metal sheets, the lower middle board, the upper metal sheets and the upper middle board with the upper surfaces of the upper metal sheets, the lower surfaces of the lower metal sheets, the lower surface of the lower middle board, and the upper surface of the upper middle board exposed from the encapsulant, and with a frame layer formed around the upper surfaces of the upper metal sheets to define a chamber together with the upper metal sheets;
mounting a photosensitive chip to the upper surface of the upper middle board and within the chamber; and
arranging a transparent layer on the frame layer of the encapsulant to cover the photosensitive chip.

5. The method according to claim 4, wherein the encapsulant is made of industrial plastic material, and the encapsulant and the frame layer are integrally formed by way of injection molding.
